(19) United States
(12) Patent Application Publication
(10) Pub. No.: US 2014/0035690 A1
(43) Pub. Date: Feb. 6, 2014

(54) VOLTAGE CHANGE COMPENSATION TYPE OSCILLATOR AND METHOD OF COMPENSATING ERROR OF OSCILLATOR

(71) Applicant: SAMSUNG ELECTRO-MECHANICS CO., LTD., Gyeonggi-do (KR)

(72) Inventor: Soo Woong Lee, Gyeonggi-do (KR)

(73) Assignee: Samsung Electro-Mechanics Co., Ltd., Gyeonggi-do (KR)

(21) Appl. No.: 13/706,611

(22) Filed: Dec. 6, 2012

(30) Foreign Application Priority Data
Jul. 31, 2012 (KR) 10-2012-0084026

(51) Int. Cl. H03L 1/00

(52) U.S. Cl. CPC H03L 1/00
USPC 331/175

(57) ABSTRACT

The present invention relates to a voltage change compensation type oscillator and a method of compensating an error of an oscillator, which includes a voltage level detecting unit; a current level adjusting unit; and an oscillating core unit for generating and outputting a clock signal by receiving a power supply voltage and an output current of the current level adjusting unit, wherein the current level adjusting unit adjusts the output current in proportion to an increase of the voltage level detected by the voltage level detecting unit, thus remarkably reducing a frequency error of the clock signal in spite of changes in voltage.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2012-0084026, entitled filed Jul. 31, 2012, which is hereby incorporated by reference in its entirety into this application.

### BACKGROUND OF THE INVENTION

1. Field of the Invention

The present invention relates to a voltage change compensation type oscillator and a method of compensating an error of an oscillator.

2. Description of the Related Art

An oscillator means an oscillator that generates a clock signal of a predetermined frequency. In the design of a typical oscillator, there are important parameters related to an output frequency, such as capacitors, resistance, and current.

A deviation of the output frequency of the oscillator occurs according to changes in process, voltage, temperature (PVT). Particularly, in Patent Document 1 and the like, techniques for compensating a deviation due to changes in temperature are disclosed.

Meanwhile, FIG. 1 is a view schematically showing changes in frequency output from an oscillator according to a level of a voltage input into the conventional typical oscillator, and FIG. 2 is a view showing changes in charge and discharge currents according to the level of the voltage input into the conventional typical oscillator.

When a power supply voltage of the oscillator is increased, a current of the capacitor is increased. Accordingly, since charge and discharge time of electric charges is increased, consequently, the output frequency of the oscillator is reduced.

That is, the power supply voltage applied to the oscillator and the output frequency output from the oscillator have an inverse relationship. This phenomenon can be easily understood through FIGS. 1 and 2.

However, so far, techniques for compensating a deviation of an output frequency of an oscillator due to changes in voltage have not been proposed.

### RELATED ART DOCUMENT

### Patent Document

Patent Document 1: Korean Patent Laid-open Publication No. 10-2004-0101240

### SUMMARY OF THE INVENTION

The present invention has been invented in order to overcome the above-described problems and it is, therefore, an object of the present invention to provide a voltage change compensation type oscillator capable of reducing an error of an oscillator due to changes in voltage.

Further, it is another object of the present invention to provide a method of compensating an error of an oscillator that can reduce an error of an oscillator due to changes in voltage.

In accordance with one aspect of the present invention to achieve the object, there is provided a voltage change compensation type oscillator including: a voltage level detecting unit for detecting a level of a power supply voltage; a current level adjusting unit connected to the voltage level detecting unit and adjusting a current level according to the voltage level detected by the voltage level detecting unit; and an oscillating core unit for generating and outputting a clock signal by receiving the power supply voltage and an output current of the current level adjusting unit, wherein the current level adjusting unit may adjust the output current in proportion to an increase of the voltage level detected by the voltage level detecting unit.

At this time, the current level detecting unit may include a first transistor having a first terminal to which the power supply voltage is applied; a second transistor in a mirroring relationship with the first transistor; at least one additional transistor in a mirroring relationship with the first transistor and having a second terminal connected or disconnected from a second terminal of the second transistor through a switch; and an output terminal for outputting the output current by adding a current flowing in the second terminal of the second transistor and a current flowing in the additional transistor.

Further, the voltage level detecting unit may generate different numbers of switch turn-on signals according to changes in the power supply voltage, wherein the number of the switch turn-on signals may be proportional to an increase of the power supply voltage, and each switch turn-on signal may be applied to each switch connected to the additional transistor.

Further, the voltage level detecting unit may generate a switch turn-on signal which turns on each switch connected to the additional transistor, wherein the number of the switch turn-on signals may be proportional to the increase of the power supply voltage.

Further, the voltage level detecting unit may include first to Nth level detecting units, wherein the first level detecting unit may include a first comparator having a first terminal to which the power supply voltage is applied and a second terminal to which a first reference voltage is applied; and a first voltage level switch having one end and a control terminal connected to an output terminal of the first comparator and the other end which is an output terminal of the first level detecting unit, and the Nth level detecting unit may include an Nth comparator having a first terminal to which a voltage of an output terminal of an N−1th level detecting unit is applied and a second terminal to which an Nth reference voltage is applied; and an Nth voltage level switch having one end and a control terminal connected to an output terminal of the Nth comparator and the other end which is an output terminal of the Nth level detecting unit, wherein N is an integer greater than 1, and a difference between a second reference voltage and the first reference voltage is equal to a difference between the Nth reference voltage and an N−1th reference voltage.

At this time, the first voltage level switch and the Nth voltage level switch may be P-type MOS transistors.

Further, the voltage change compensation type oscillator may further include a first parallel voltage level switch having one end and the other end respectively connected to one end and the other end of the first voltage level switch and a control terminal to which an inverted output signal of the first comparator is applied; and an Nth parallel voltage level switch having one end and the other end respectively connected to one end and the other end of the Nth voltage level switch and a control terminal to which an inverted output signal of the Nth comparator is applied.

At this time, the first voltage level switch and the Nth voltage level switch may be P-type MOS transistors, and the first parallel voltage level switch and the Nth parallel voltage level switch may be N-type MOS transistors.

In accordance with another aspect of the present invention to achieve the object, there is provided a voltage change compensation type oscillator including: a voltage level detecting unit for detecting a level of a power supply voltage by including first to Nth level detecting units; a current level adjusting unit for adjusting a current level according to changes in the power supply voltage; and an oscillator core unit for generating and outputting a clock signal by receiving an output current of the current level adjusting unit and the power supply voltage.

The first level detecting unit may include a first comparator having a first terminal to which the power supply voltage is applied and a second terminal to which a first reference voltage is applied; and a first voltage level switch having one end and a control terminal connected to an output terminal of the first comparator and the other end which is an output terminal of the first level detecting unit.

The Nth level detecting unit may include an Nth comparator having a first terminal to which a voltage of an output terminal of an N−1th level detecting unit is applied and a second terminal to which an Nth reference voltage is applied; and an Nth voltage level switch having one end and a control terminal connected to an output terminal of the Nth comparator and the other end which is an output terminal of the Nth level detecting unit.

The current level detecting unit may include a first transistor having a first terminal to which the power supply voltage is applied; a second transistor in a mirroring relationship with the first transistor; a first additional transistor in a mirroring relationship with the first transistor and having a second terminal connected or disconnected from a second terminal of the second transistor through a first switch; an Nth additional transistor in a mirroring relationship with the first transistor and having a second terminal connected to a second terminal of an N−1th additional transistor through an N−1th switch; and an output terminal for outputting the output current by adding a current flowing in the second terminal of the second transistor and a current flowing in the first to Nth additional transistors.

N is an integer greater than 1 and a difference between a second reference voltage and the first reference voltage is equal to a difference between the Nth reference voltage and an N−1th reference voltage. The first voltage level switch and the first switch are turned on or off at the same time and the Nth voltage level switch and the Nth additional transistor are turned on or off at the same time.

At this time, the voltage change compensation type oscillator may further include a first parallel voltage level switch having one end and the other end respectively connected to one end and the other end of the first voltage level switch and a control terminal to which an inverted output signal of the first comparator is applied; and an Nth parallel voltage level switch having one end and the other end respectively connected to one end and the other end of the Nth voltage level switch and a control terminal to which an inverted output signal of the Nth comparator is applied.

Further, the first voltage level switch and the Nth voltage level switch may be P-type MOS transistors, and the first parallel voltage level switch and the Nth parallel voltage level switch may be N-type MOS transistors.

Further, the voltage change compensation type oscillator may further include a first parallel switch having one end and the other end respectively connected to one end and the other end of the first switch and a control terminal to which an inverted output signal of the first comparator is applied; and an Nth parallel switch having one end and the other end respectively connected to one end and the other end of the Nth switch and a control terminal to which an inverted output signal of the Nth comparator is applied.

At this time, the first switch and the Nth switch may be P-type MOS transistors, and the first parallel switch and the Nth parallel switch may be N-type MOS transistors.

Further, the oscillator core unit may include a current mirror for an oscillator core for mirroring an output voltage of the current level adjusting unit; and a ring oscillator having one end to which the power supply voltage is applied and the other end connected to the current mirror.

In accordance with another aspect of the present invention to achieve the object, there is provided a method of compensating an error of an oscillator by setting a voltage section by dividing the range in which a power supply voltage can be increased into predetermined voltage intervals and dividing the voltage section into the M voltage sections in the order in which an increase of the power supply voltage is increased, including the steps of: (A) determining to which section the increase of the power supply voltage corresponds among the M voltage sections by detecting the increase of the power supply voltage; and (B) adjusting the size of a current applied to the oscillator according to the result of determination in the step (A).

At this time, the current applied to the oscillator may be increased in proportion to the increase of the power supply voltage and changed only when the voltage section to which the increase of the power supply voltage corresponds is changed.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a view schematically showing changes in frequency output from an oscillator according to a level of a voltage input into the conventional typical oscillator;

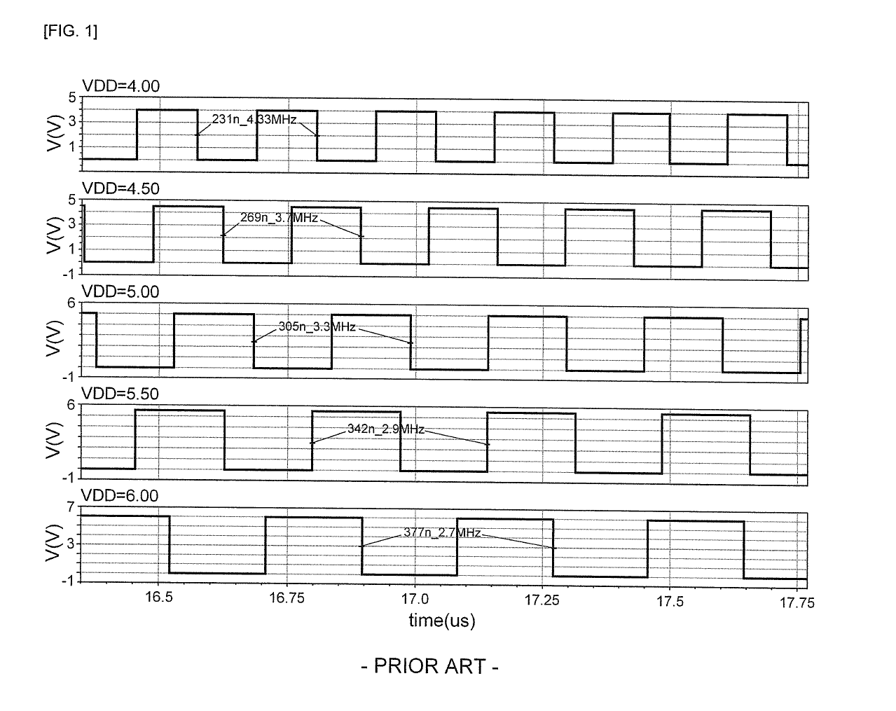

FIG. 2 is a view showing changes in charge and discharge currents according to the level of the voltage input into the conventional typical oscillator;

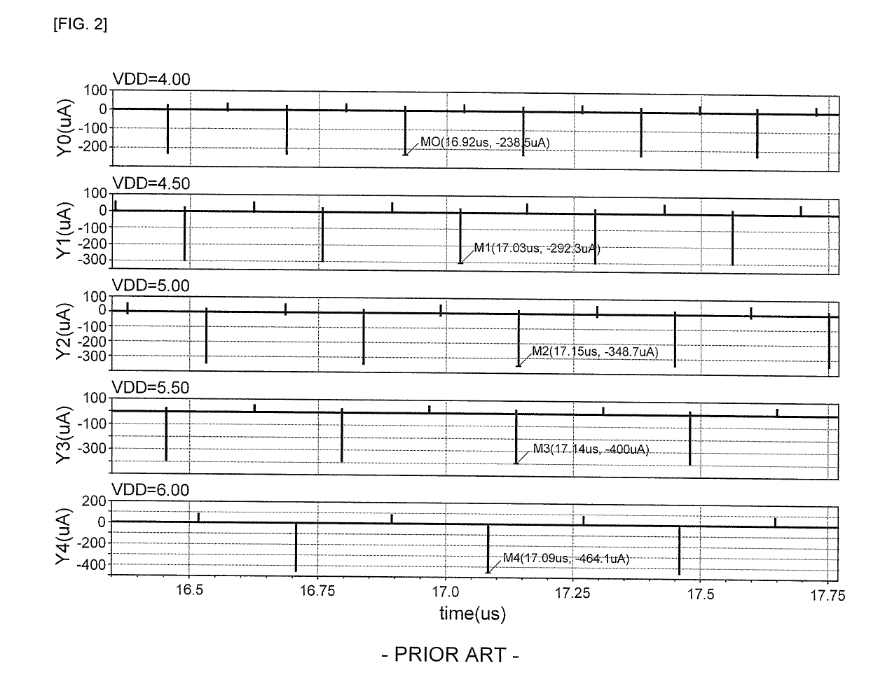

FIG. 3 is a view schematically showing a voltage change compensation type oscillator in accordance with an embodiment of the present invention;

FIG. 4 is a view schematically showing a voltage level detecting unit of the voltage change compensation type oscillator in accordance with an embodiment of the present invention;

FIG. 5 is a view schematically showing a current level adjusting unit of the voltage change compensation type oscillator in accordance with an embodiment of the present invention;

FIG. 6 is a view schematically showing an oscillator core unit of the voltage change compensation type oscillator in accordance with an embodiment of the present invention;

FIG. 7 is a view schematically showing changes in output frequency according to a level of a voltage input into the voltage change compensation type oscillator in accordance with an embodiment of the present invention; and

FIG. 8 is view comparing frequencies and frequency errors of the voltage change compensation type oscillator in accordance with an embodiment of the present invention and the conventional typical oscillator.

### DETAILED DESCRIPTION OF THE PREFERABLE EMBODIMENTS

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art. The same reference numerals refer to the same elements throughout the specification.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help understanding of embodiments of the present invention. The same reference numerals in different figures denote the same elements and the similar reference numerals do not necessarily all refer to the similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

Hereinafter, configuration and operational effect of the present invention will be described in detail with reference to the drawings.

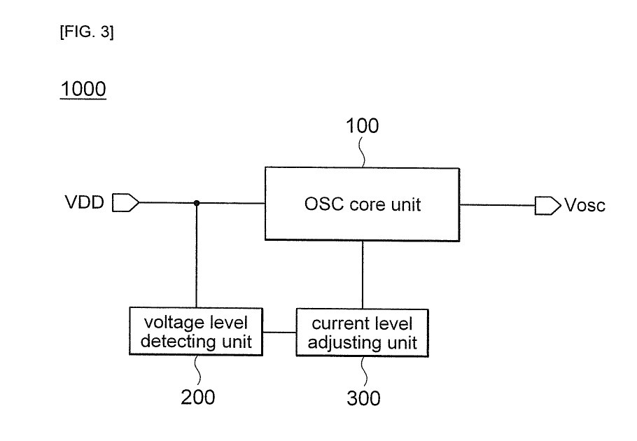

FIG. 3 is a view schematically showing a voltage change compensation type oscillator 1000 in accordance with an embodiment of the present invention.

Referring to FIG. 3, a voltage change compensation type oscillator 1000 in accordance with an embodiment of the present invention may include a voltage level detecting unit 200, a current level adjusting unit 300, and an oscillator core unit 100.

The voltage level detecting unit 200 performs functions of receiving a power supply voltage VDD and detecting a level of the power supply voltage VDD.

The current level adjusting unit 300 performs a function of providing an output current of which a current level is adjusted according to the voltage level to the oscillator core unit 100.

The oscillator core unit 100 generates and outputs a clock signal of a predetermined frequency by receiving the power supply voltage VDD and the output current of the current level adjusting unit 300.

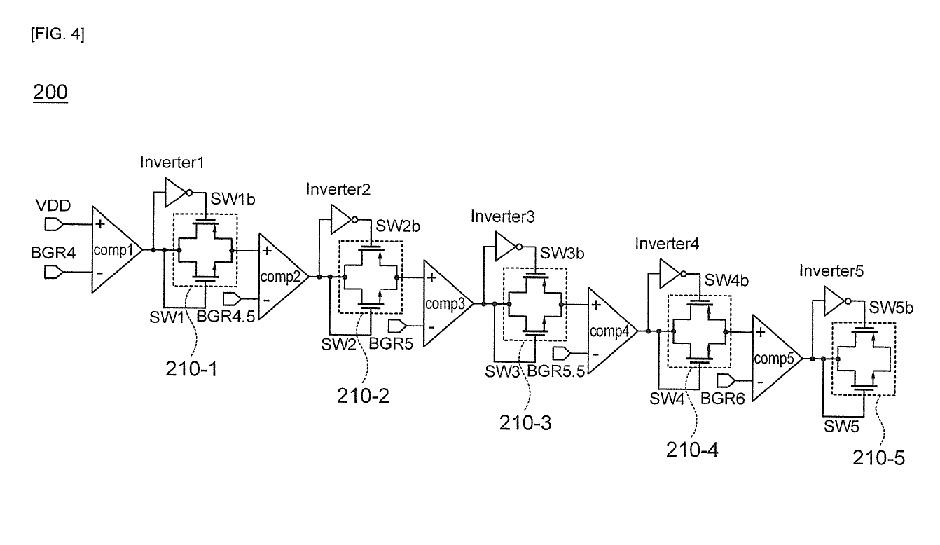

FIG. 4 is a view schematically showing the voltage level detecting unit 200 of the voltage change compensation type oscillator 1000 in accordance with an embodiment of the present invention.

Referring to FIG. 4, the voltage level detecting unit 200 of the voltage change compensation type oscillator 1000 in accordance with an embodiment of the present invention may include a plurality of comparators comp1, comp2, comp3, comp4, and comp5 and a plurality of voltage level switches 210-1, 210-2, 210-3, 210-4, and 210-5.

Predetermined reference voltages may be applied to inverting terminals of the comparators, respectively.

At this time, BGR4, BGR4.5, etc. shown in the drawing mean a band gap reference voltage of 4V, a band gap reference voltage of 4.5V, etc.

That is, the reference voltages, which are sequentially increased by 0.5V, are provided to the respective comparators as comparison reference voltages in the drawing, and it should be understood that this interval can be set differently according to the need.

Meanwhile, the voltage level switch is provided in an output terminal of the comparator.

One end and a control terminal of the voltage level switch may be connected to the output terminal of the comparator, and the other end thereof may be connected to a non-inverting terminal of the next comparator.

At this time, a pair of the comparator and the voltage level switch may be referred to as a level detecting unit.

More specifically, first, the power supply voltage VDD is applied to a non-inverting terminal of a first comparator, and a first reference voltage is applied to an inverting terminal of the first comparator.

Further, an output terminal of the first comparator is connected to one end and a control terminal of a first voltage level switch 210-1.

Next, the other end of the first voltage level switch 210-1 is connected to a non-inverting terminal of a second comparator.

Further, a second reference voltage is applied to an inverting terminal of the second comparator.

At this time, the second reference voltage may be a value increased by a predetermined value than the first reference voltage, and FIG. 4 shows the case in which the increased value is 0.5V.

Further, an output terminal of the second comparator is connected to one end and a control terminal of a second voltage level switch 210-2.

The first comparator and the first voltage level switch 210-1 together may be referred to as a first level detecting unit, and a second level detecting unit, a third level detecting unit, a fourth level detecting unit, and a fifth level detecting unit may be implemented by a similar principle.

Further, the number of the level detecting units may be further increased according to the need, and the interval in which the reference voltage is increased also may be increased.

For example, an operation principle of the voltage level detecting unit 200 when the power supply voltage VDD is 4.7V will be described below.

First, since the power supply voltage VDD of 4.7V is higher than the first reference voltage of 4V, 4.7V is output from the output terminal of the first comparator.

Next, as the output voltage of 4.7V of the first comparator is applied to the control terminal of the first voltage level switch 210-1, the first voltage level switch 210-1 is turned on and the output voltage of 4.7V of the first comparator is applied to the non-inverting terminal of the second comparator through the first voltage level switch 210-1.

Next, since the voltage of 4.7V applied to the non-inverting terminal of the second comparator is higher than the second reference voltage of 4.5V, 4.7V is output from the output terminal of the second comparator and applied to a non-inverting terminal of a third comparator while turning on the second voltage level switch 210-2.

Next, in the third comparator, since a third reference voltage of 5.0V is higher than 4.7V applied to the non-inverting terminal of the third comparator, a low signal is output from an output terminal of the third comparator and the third voltage level switch 210-3 maintains an off-state.

By the above principle, in the voltage level detecting unit 200, the number of the turned-on voltage level switches is changed according to the size of the power supply voltage VDD.

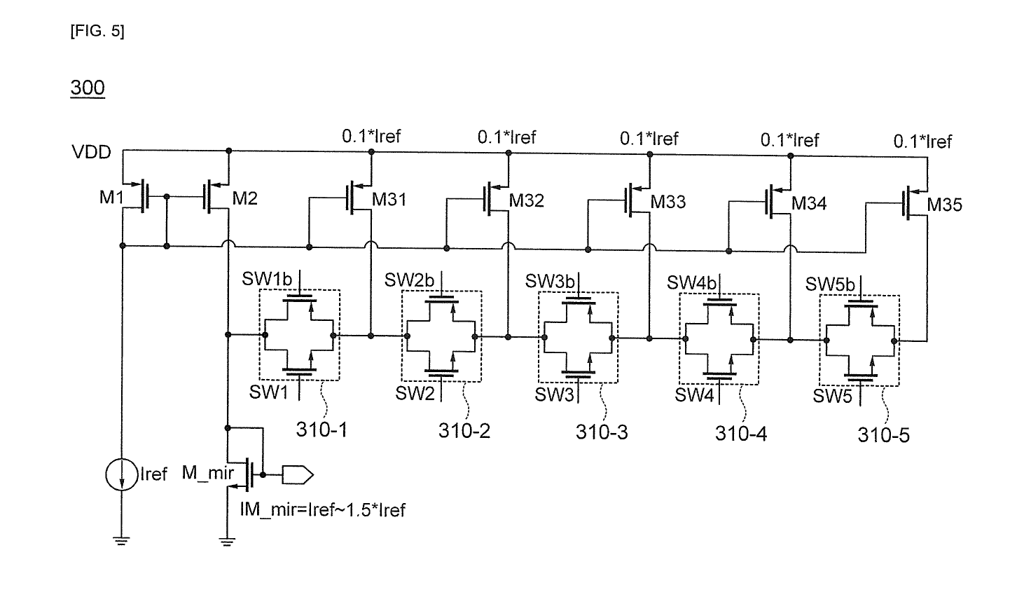

FIG. 5 is a view schematically showing the current level adjusting unit 300 of the voltage change compensation type oscillator 1000 in accordance with an embodiment of the present invention.

Referring to FIG. 5, the current level adjusting unit 300 of the voltage change compensation type oscillator 1000 in accordance with an embodiment of the present invention may include a first transistor M1, a second transistor M2, and a plurality of additional transistors.

The second transistor M2 and the additional transistor have a mirroring relationship with the first transistor M1.

At this time, a switch is provided between a second terminal of the additional transistor and an output terminal of the current level adjusting unit. Further, this switch is turned on or off simultaneously with the above-described voltage level switch.

More specifically, a second terminal of a first additional transistor 31 is connected or disconnected from a second terminal of the second transistor M2 by a first switch 310-1.

Further, a second terminal of a second additional transistor 32 is connected or disconnected from the second terminal of the first additional transistor 31 by a second switch 310-2.

In a similar way, a second terminal of a fifth additional transistor 35 is connected or disconnected from a second terminal of a fourth transistor by a fifth switch 310-5.

At this time, since the first to fifth switches 310-1 to 310-5 operate in the same way as the first to fifth voltage level switches 210-1 to 210-5, as described above, when the power supply voltage VDD is 4.7V, only the first switch 310-1 and the second switch 310-2 are turned on and the remaining switches are turned off.

Accordingly, a current output from the current level adjusting unit 300 becomes 1.2 times the reference current Iref.

That is, the number of the turned-on voltage level switches is determined according to the level of the power supply voltage VDD detected by the voltage level detecting unit 200, and as the same number of the switches is turned on, the current output from the current level adjusting unit 300 can be adjusted.

Meanwhile, the voltage level switch and the switch may be implemented as P-type MOS transistors.

Further, as shown in FIGS. 4 and 5, a parallel voltage level switch and a parallel switch may be implemented as N-type MOS transistors and operated on the same principle as that described above by applying inverted signals to control terminals thereof. When implemented like this, it is possible to further implement an effect of reducing resistance due to the switch.

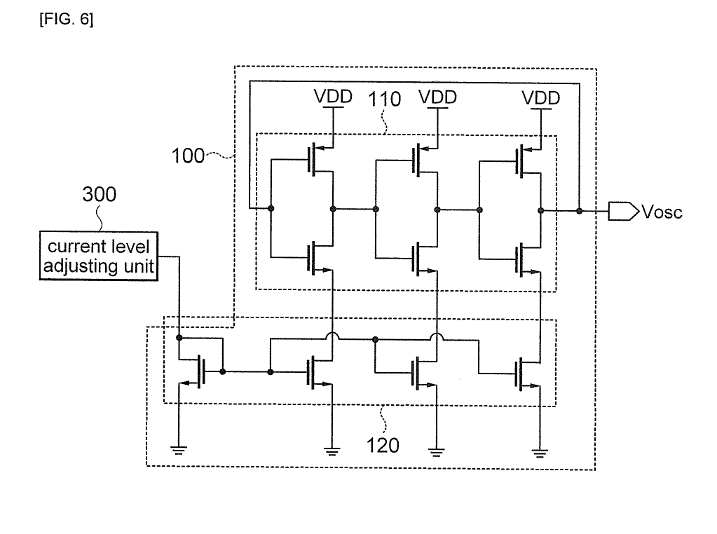

FIG. 6 is a view schematically showing the oscillator core unit 100 of the voltage change compensation type oscillator 1000 in accordance with an embodiment of the present invention.

Referring to FIG. 6, the oscillator core unit 100 of the voltage change compensation type oscillator 1000 in accordance with an embodiment of the present invention may include a ring oscillator 110 and a current mirror 120 for an oscillator core.

Similarly to the general case, the ring oscillator 110 may be implemented by connecting the series-connected N-type MOS transistor and P-type MOS transistor in three stages. The power supply voltage VDD may be applied to one end of the series-connected N-type MOS transistor and P-type MOS transistor, and a current source may be connected to the other end of the series-connected N-type MOS transistor and P-type MOS transistor.

At this time, in an embodiment of the present invention, it is implemented that the output current of the above-described current level adjusting unit 300 is applied to each branch using the current mirror 120 for an oscillator core.

Accordingly, although the power supply voltage VDD is changed, the current, which can compensate the change in the power supply voltage VDD, can be provided to the ring oscillator 110. Thus, it is possible to reduce a frequency error of the clock signal output from the oscillator.

Meanwhile, although FIG. 6 shows that the ring oscillator 110 is implemented by connecting the series-connected N-type MOS transistor and P-type MOS transistor in three stages, the ring oscillator 110 may be implemented by connecting the series-connected N-type MOS transistor and P-type MOS transistor in an odd number of stages, that is, five stages, seven stages, nine stages and so on.

Further, although FIG. 6 shows that the oscillator core unit 100 is implemented by including the ring oscillator 110, the oscillator core unit 100 may be implemented by applying various types of oscillators such as an RC oscillator in addition to the ring oscillator 110.

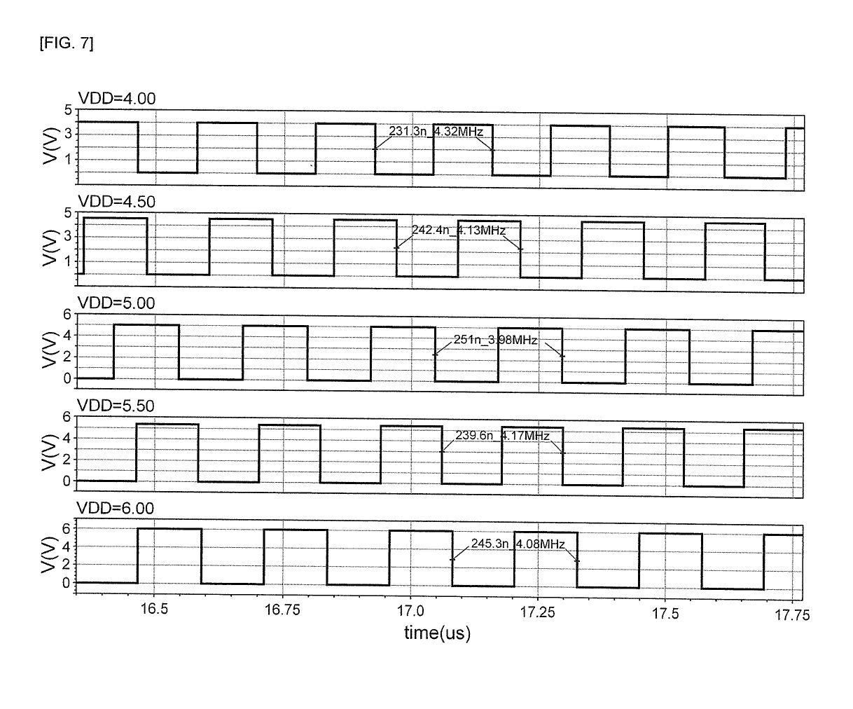

FIG. 7 is a view schematically showing changes in output frequency according to the level of the voltage input into the voltage change compensation type oscillator 1000 in accordance with an embodiment of the present invention.

Referring to FIG. 7, although the power supply voltage VDD is changed in the range of 4 to 6V, it is possible to check that a frequency of the clock signal is maintained in the range of 3.98 to 4.32 MHz.

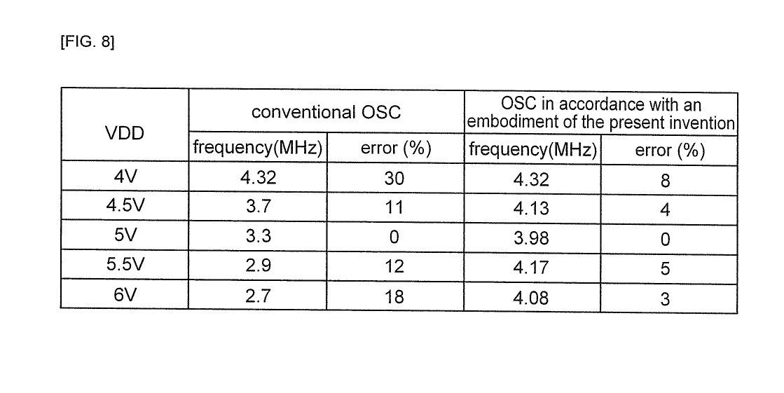

FIG. 8 is a view comparing frequencies and frequency errors of the voltage change compensation type oscillator 1000 in accordance with an embodiment of the present invention and a conventional typical oscillator.

Referring to FIG. 8, it is possible to check that a variation of frequency in the voltage change compensation type oscillator 1000 in accordance with an embodiment of the present invention is remarkably reduced in spite of the change in the power supply voltage VDD compared to the conventional oscillator.

It is possible to understand a method of compensating an error of an oscillator in accordance with an embodiment of the present invention based on the foregoing description.

That is, the method of compensating an error of an oscillator in accordance with an embodiment of the present invention may include a process of determining to which section an increase of a power supply voltage corresponds among the M voltage sections and a process of adjusting the size of a current applied to an oscillator according to the result of determination.

At this time, the voltage section may be set by dividing the range in which the power supply voltage can be increased into predetermined voltage intervals, and the voltage section may be divided into the M voltage sections in the order in which the increase of the power supply voltage is increased.

Further, the current applied to the oscillator may be increased in proportion to the increase of the power supply voltage and changed only when the voltage section to which the increase of the power supply voltage corresponds is changed.

The voltage change compensation type oscillator in accordance with an embodiment of the present invention configured as above can effectively reduce an error of an oscillator due to changes in voltage.

Further, the method of compensating an error of an oscillator in accordance with an embodiment of the present invention can efficiently reduce an error of an oscillator due to changes in voltage.

What is claimed is:

1. A voltage change compensation type oscillator comprising:
a voltage level detecting unit for detecting a level of a power supply voltage;
a current level adjusting unit connected to the voltage level detecting unit and adjusting a current level according to the voltage level detected by the voltage level detecting unit; and
an oscillating core unit for generating and outputting a clock signal by receiving the power supply voltage and an output current of the current level adjusting unit, wherein the current level adjusting unit adjusts the output current in proportion to an increase of the voltage level detected by the voltage level detecting unit.

2. The voltage change compensation type oscillator according to claim 1, wherein the current level detecting unit comprises:
a first transistor having a first terminal to which the power supply voltage is applied;
a second transistor in a mirroring relationship with the first transistor;
at least one additional transistor in a mirroring relationship with the first transistor and having a second terminal connected or disconnected from a second terminal of the second transistor through a switch; and
an output terminal for outputting the output current by adding a current flowing in the second terminal of the second transistor and a current flowing in the additional transistor.

3. The voltage change compensation type oscillator according to claim 2, wherein the voltage level detecting unit generates different numbers of switch turn-on signals according to changes in the power supply voltage, wherein the number of the switch turn-on signals is proportional to an increase of the power supply voltage, and
each switch turn-on signal is applied to each switch connected to the additional transistor.

4. The voltage change compensation type oscillator according to claim 2, wherein the voltage level detecting unit generates a switch turn-on signal which turns on each switch connected to the additional transistor, wherein the number of the switch turn-on signals is proportional to an increase of the power supply voltage.

5. The voltage change compensation type oscillator according to claim 1, wherein the voltage level detecting comprises first to Nth level detecting units, wherein the first level detecting unit comprises:
a first comparator having a first terminal to which the power supply voltage is applied and a second terminal to which a first reference voltage is applied; and
a first voltage level switch having one end and a control terminal connected to an output terminal of the first comparator and the other end which is an output terminal of the first level detecting unit, the Nth level detecting comprises:
an Nth comparator having a first terminal to which a voltage of an output terminal of an N−1th level detecting unit is applied and a second terminal to which an Nth reference voltage is applied; and
an Nth voltage level switch having one end and a control terminal connected to an output terminal of the Nth comparator and the other end which is an output terminal of the Nth level detecting unit,
N is an integer greater than 1, and
a difference between a second reference voltage and the first reference voltage is equal to a difference between the Nth reference voltage and an N−1th reference voltage.

6. The voltage change compensation type oscillator according to claim 5, wherein the first voltage level switch and the Nth voltage level switch are P-type MOS transistors.

7. The voltage change compensation type oscillator according to claim 5, further comprising:
a first parallel voltage level switch having one end and the other end respectively connected to one end and the other end of the first voltage level switch and a control terminal to which an inverted output signal of the first comparator is applied; and
an Nth parallel voltage level switch having one end and the other end respectively connected to one end and the other end of the Nth voltage level switch and a control terminal to which an inverted output signal of the Nth comparator is applied.

8. The voltage change compensation type oscillator according to claim 7, wherein the first voltage level switch and the Nth voltage level switch are P-type MOS transistors, and the first parallel voltage level switch and the Nth parallel voltage level switch are N-type MOS transistors.

9. A voltage change compensation type oscillator comprising:
a voltage level detecting unit for detecting a level of a power supply voltage by comprising first to Nth level detecting units;
a current level adjusting unit for adjusting a current level according to changes in the power supply voltage; and
an oscillator core unit for generating and outputting a clock signal by receiving an output current of the current level adjusting unit and the power supply voltage, wherein the first level detecting unit comprises:
a first comparator having a first terminal to which the power supply voltage is applied and a second terminal to which a first reference voltage is applied; and
a first voltage level switch having one end and a control terminal connected to an output terminal of the first comparator and the other end which is an output terminal of the first level detecting unit, the Nth level detecting unit comprises:
an Nth comparator having a first terminal to which a voltage of an output terminal of an N−1th level detecting unit is applied and a second terminal to which an Nth reference voltage is applied; and
an Nth voltage level switch having one end and a control terminal connected to an output terminal of the Nth comparator and the other end which is an output terminal of the Nth level detecting unit, the current level detecting unit comprises:
a first transistor having a first terminal to which the power supply voltage is applied;
a second transistor in a mirroring relationship with the first transistor;
a first additional transistor in a mirroring relationship with the first transistor and having a second terminal connected or disconnected from a second terminal of the second transistor through a first switch;
an Nth additional transistor in a mirroring relationship with the first transistor and having a second terminal connected to a second terminal of an N−1th additional transistor through an N−1th switch; and
an output terminal for outputting the output current by adding a current flowing in the second terminal of the second transistor and a current flowing in the first to Nth additional transistors, and
N is an integer greater than 1 and a difference between a second reference voltage and the first reference voltage is equal to a difference between the Nth reference voltage and an N−1th reference voltage,
the first voltage level switch and the first switch are turned on or off at the same time, and
the Nth voltage level switch and the Nth additional transistor are turned on or off at the same time.

10. The voltage change compensation type oscillator according to claim 9, wherein the first voltage level switch, the Nth voltage level switch, the first switch, and the Nth switch are P-type MOS transistors.

11. The voltage change compensation type oscillator according to claim 9, further comprising:
a first parallel voltage level switch having one end and the other end respectively connected to one end and the other end of the first voltage level switch and a control terminal to which an inverted output signal of the first comparator is applied; and
an Nth parallel voltage level switch having one end and the other end respectively connected to one end and the other end of the Nth voltage level switch and a control terminal to which an inverted output signal of the Nth comparator is applied.

12. The voltage change compensation type oscillator according to claim 11, wherein the first voltage level switch and the Nth voltage level switch are P-type MOS transistors, and the first parallel voltage level switch and the Nth parallel voltage level switch are N-type MOS transistors.

13. The voltage change compensation type oscillator according to claim 9, further comprising:
a first parallel switch having one end and the other end respectively connected to one end and the other end of the first switch and a control terminal to which an inverted output signal of the first comparator is applied; and
an Nth parallel switch having one end and the other end respectively connected to one end and the other end of the Nth switch and a control terminal to which an inverted output signal of the Nth comparator is applied.

14. The voltage change compensation type oscillator according to claim 13, wherein the first switch and the Nth switch are P-type MOS transistors, and the first parallel switch and the Nth parallel switch are N-type MOS transistors.

15. The voltage change compensation type oscillator according to claim 9, wherein the oscillator core unit comprises:
a current mirror for an oscillator core for mirroring an output voltage of the current level adjusting unit; and
a ring oscillator having one end to which the power supply voltage is applied and the other end connected to the current mirror.

16. A method of compensating an error of an oscillator by setting a voltage section by dividing the range in which a power supply voltage can be increased into predetermined voltage intervals and dividing the voltage section into the M voltage sections in the order in which an increase of the power supply voltage is increased, comprising:
(A) determining to which section the increase of the power supply voltage corresponds among the M voltage sections by detecting the increase of the power supply voltage; and
(B) adjusting the size of a current applied to the oscillator according to the result of determination in the step (A).

17. The method of compensating an error of an oscillator according to claim 16, wherein the current applied to the oscillator is increased in proportion to the increase of the power supply voltage and changed only when the voltage section to which the increase of the power supply voltage corresponds is changed.
